(19) United States
(12) Patent Application Publication
(10) Pub. No.: US 2024/0096671 A1
(43) Pub. Date: Mar. 21, 2024

(54) SUBSTRATE CONTAINER SYSTEMS AND METHODS OF PURGING A SUBSTRATE CONTAINER

(71) Applicant: ENTEGRIS, INC., Billerica, MA (US)

(72) Inventors: Matthew A. Fuller, Colorado Springs, CO (US); Gary Gallagher, Austin, TX (US); Thomas Martin Adrian, Mound, MN (US)

(21) Appl. No.: 18/370,337

(22) Filed: Sep. 19, 2023

Related U.S. Application Data
(60) Provisional application No. 63/408,028, filed on Sep. 19, 2022.

(51) Int. Cl. H01L 21/673

(52) U.S. Cl. CPC H01L 21/67393; H01L 21/67383; H01L 21/67386

(57) ABSTRACT

Described are substrate containers that are useful for holding or transporting substrates such as semiconductor wafers and microelectronic devices, in a clean environment, as well as methods of using the substrate containers.

### FIELD

The present disclosure relates to substrate containers (sometimes referred to as “substrate carriers” or “wafer containers”) that are useful for holding or transporting “substrates” (e.g., semiconductor wafers or the like) in a clean environment, as well as methods of using the substrate containers.

### BACKGROUND

Microelectronic devices are prepared on semiconductor substrates by a series of precise processing steps, each being performed under exceedingly clean conditions. Between processing steps, a “substrate” onto which the microelectronic devices are being formed may be moved from one processing location to a different processing location.

To move substrates between processing steps or separate processing locations, the substrates are held in specialized containers that are designed to prevent the substrates from being damaged, while also shielding the substrates from contamination. Example substrate containers may be referred to as “SMIF pods” (Standard Mechanical Interface pods), “FOUPs” (Front Opening Unified Pods), or “FOSBs” (Front Opening Shipping Box). During use, these containers enclose a space to contain multiple semiconductor wafers or other substrates within an atmosphere that may be evacuated (i.e., that is under reduced pressure) or that may contain a gas that is different from air, e.g., an inert gas.

A substrate container may be in the form of a multi-sided container body (e.g., a “shell”) that defines a container interior. The container body includes an opening on one side that allows multiple substrates to be inserted into the interior or removed from the interior. The container also includes a removable door that is adapted to cover the opening to enclose the interior with an air-tight seal. One or more gas ports (inlets or outlets) pass through the body of the container to allow gases to be introduced into the interior to control the atmosphere within the container.

As microelectronic devices become smaller and the number of microelectronic features per area of semiconductor devices increases, the devices become more sensitive to particle and environmental contaminants. With smaller microelectronic devices, contaminants having smaller and smaller sizes, even contaminants on a molecular scale, are capable of disrupting the performance of a microelectronic device. Consequently, ever-improving control of particle contamination is required during all phases of processing semiconductor substrates, including during transport of substrates between process steps.

There is ongoing need for ever-improving systems and methods of controlling gaseous environments within substrate containers to maintain a high level of cleanliness and to avoid contaminating the substrates during handling.

### SUMMARY

During use of a substrate container, for various reasons, the gaseous atmosphere within the container interior may be replaced by a new gaseous atmosphere. To allow this, a container may include gas ports (i.e., openings or “inlets”) through which gas can be delivered to or removed from the container interior.

As an example, a highly pure, clean, and dry gas (referred to as a “purge gas”) may be dispensed into a container interior to replace (i.e., displace) a previous atmosphere. When substrates are inserted into a container interior, the substrates may contain moisture at their surfaces, which can pass into the container atmosphere. At a desired time before removing the substrates from the container interior, either before or after the container door is removed, the container atmosphere may be replaced with a new gaseous atmosphere that contains no moisture, i.e., the container interior is “purged” with a dry atmosphere. Some purge methods use nitrogen as a dry purge gas to replace the container atmosphere. Other purge methods use clean dry air as the purge gas.

The choice of using either nitrogen or clean dry air as a purge gas can depend on the type of substrate being processed, the types of processes being performed on the substrates, and a user's preference. A purpose of a purge step can be to remove moisture vapor from the container. Either nitrogen or clean dry air is effective to remove moisture. But some processes are sensitive to the presence of oxygen. For these processes, nitrogen gas has a benefit of lowering an oxygen level in the container, as opposed to clean dry air, which contains oxygen. Still, clean dry air is a purge gas of choice for manufacturing processes that are not highly sensitive to the presence of oxygen, and where the cost of nitrogen gas is relatively high or prohibitive. To the Applicant's knowledge, commercial processes use one or the other of nitrogen or clean dry air, but do not use a purge gas that is a mixture or combination of clean dry air with nitrogen.

In addition to being effective to remove moisture, a preferred commercial purge step should be performed with efficient throughput. A length of time needed to perform a purge step can be important in this respect. Longer times required for a purge step will reduce throughput and overall efficiency of a manufacturing process, while reduced times required for a purge step will advantageously increase throughput and overall efficiency.

As determined by the Applicant, commercial processes that use one or the other of nitrogen gas (pure nitrogen) or clean dry air, alone, and without accounting for the density of the selected purge gas, produce non-uniform purging of a substrate container between upper container locations and lower container locations. The non-uniform purging causes extended amounts of time for completing a purge step.

In more detail, a container atmosphere contains moisture due to moisture that is present at substrate surfaces when the substrates are placed within the container interior, or due to an amount of moisture in the container atmosphere when the atmosphere is enclosed within the container interior, or both. Because dry air as a purge gas is more dense than the moist air of the container atmosphere, dry air as a purge gas tends to flow through a lower portion of a substrate container interior quickly, while requiring a significantly longer period of time to eventually replace the less-dense humid atmosphere at upper container locations. Conversely, nitrogen as a purge gas is lighter than moist air and displaces the atmosphere of the upper container locations quickly, but requires a significantly longer amount of time to replace the atmosphere at the lower portion of the container.

As determined by the Applicant, the uniformity of a flow of purge gas through upper and lower portions of a substrate container interior can be improved by controlling the density of the purge gas, by using a purge gas that has a density that is approximately the same as the density of the container atmosphere. A purge gas that has a density that approximates the density of the humid air within the container interior will displace the humid air at the upper container locations and the lower container locations in a significantly more uniform manner. With more uniform flow of the purge gas through the container, the amount of time required for a purge step is reduced compared to an amount of time that would be required using a purge gas that has a density that is significantly different from the density of the container atmosphere.

As described herein, density of a purge gas may be selected and controlled to match a density of an atmosphere present in a substrate container interior, in a manner that improves uniformity of flow of the purge gas through the container interior and reduces an amount of time required to complete a purge step. The density of the purge gas may be controlled by selecting a composition of the purge gas that has a density that approximates the density of the humid air contained in the container interior. The purge gas may be a mixture of two different types of purge gases, such as clean dry air or oxygen mixed with nitrogen (pure nitrogen), and the mixture can have a density that is approximately equal to the density of the humid air of the container atmosphere. Alternately or additionally, the purge gas may be a single type of purge gas (e.g., pure nitrogen gas or clean dry air), or a combination of different purge gas components (e.g., nitrogen and oxygen) that is at a temperature at which the purge gas has a density that is approximately equal to the density of the humid air of the container atmosphere.

In one aspect, the invention relates to a method of purging a substrate container with purge gas. The substrate container includes: a container body comprising an opening; a door adapted to cover the opening; an interior defined by the container body; substrates supported within the interior; a container atmosphere within the interior; and one or more purge gas inlets at the interior. The method includes dispensing purge gas through the one or more inlets to the interior and the purge gas comprises: clean dry air received from a source of clean dry air, and nitrogen gas received from a source of nitrogen gas.

In another aspect the invention relates to a method of purging a substrate container with purge gas. The substrate container includes: a container body comprising an opening; a door adapted to cover the opening; an interior defined by the container body; substrates supported within the interior; a container atmosphere within the interior; a purge gas inlet at the interior; and a source of purge gas. The method includes: measuring relative humidity of the container atmosphere, controlling a density of the purge gas based on the relative humidity of the container atmosphere, and dispensing the purge gas through the inlet and into the interior.

In yet another aspect, the invention relates to a substrate container system that includes: a container body having an opening, a door adapted to be placed over and removed from the opening, an interior defined by the container body, substrates supported within the interior, a container atmosphere within the interior, a purge gas inlet at the interior, and a source of purge gas that includes a source of clean dry air and a source of nitrogen gas. The system also includes a purge gas flow control system that combines a flow of the clean dry air and a flow of the nitrogen gas to produce a purge gas mixture.

According to still another aspect, the invention relates to a substrate container system that includes a container body having an opening, a door adapted to be placed over and removed from the opening, an interior defined by the container body, a purge gas inlet connected to the interior, a relative humidity sensor, a source of purge gas, and a control system to control a density of purge gas dispensed through the purge gas inlet to the interior.

According to yet another aspect, the invention relates to a method that includes dispensing a purge gas mixture through an inlet of a substrate container, wherein the purge gas mixture includes a combination of clean dry air and nitrogen gas.

### BRIEF DESCRIPTION OF THE DRAWINGS

FIG. 1 is a perspective view of an example wafer container as described.

FIG. 2 is a side cut-away view of an example wafer container.

FIGS. 3A, 3B, and 3C are side cut-away views of a wafer container and conventional methods of purging the wafer container.

FIGS. 4A, 4B, and 4C are side cut-away views of example wafer containers of the present description.

FIGS. 5A and 5B are side cut-away views of an example wafer container as described herein, and a method of purging the wafer container.

FIGS. 6A, 6B, and 6C are side cut-away views of a wafer container and conventional methods of purging the wafer container.

FIGS. 7A and 7B are side cut-away views of an example wafer container as described and a method of purging the wafer container.

All figures are schematic and not to scale.

### DETAILED DESCRIPTION

The following describes substrate containers that include a container body that has an interior, an opening on one side of the body to access the interior, and a door that is adapted to cover and seal the opening. The container also includes one or more gas ports, including an inlet that is useful to dispense a gas (e.g., a “purge gas”) into the interior of the container.

The container can be used as a component of a system (e.g., a “substrate container system”) that includes other devices, structures, or sources of raw materials that are used with the substrate container for handling substrates in a clean environment. Example components of a substrate container system include any one or more of: a source of purge gas; optionally, separate sources of two or more different types of purge gases; sensors to measure a condition of the container, system, or a process material (purge gas), for example a temperature sensor, pressure sensor, or humidity sensor; control devices such as a temperature control device to control a temperature and thereby a density of a purge gas delivered to the container interior, or flow control devices to control a flow of a single purge gas, two different purge gases, or a mixture of two or more different purge gases (a “purge gas mixture”); a process control system to control conditions and process steps of a purge process; etc.

Also described are methods of introducing purge gas to an interior of a container while controlling the composition of the purge gas, the temperature of the purge gas, the density of the purge gas, or a combination of these. According to example methods and systems, a composition, temperature, or density of a purge gas may be selected to cause the purge gas to displace (“purge”) the atmosphere within the container with a high degree of efficiency. In example methods, to achieve efficiency in a purging step, the purge gas may be controlled to have a density that approximates the density of the atmosphere in the container that is being displaced by the purge gas. A purge gas that has a density that is similar to or the same as the density of the container atmosphere will displace the container atmosphere in a substantially uniform manner throughout the container interior, whereas a purge gas that has a density that is significantly different from the density of the container atmosphere will displace the container atmosphere in a less efficient, e.g., less uniform, and a less rapid manner.

In example methods, a purge gas may contain a mixture of two or more different types of purge gases provided from two or more separate gas sources. As an example, a system may deliver two different types of purge gas to a container interior, the two types including clean dry air as one type of purge gas and nitrogen gas as a second type of purge gas, with the clean dry air being provided from a source of clean dry air, and the nitrogen gas being provided from a source of pure nitrogen gas. As another example, instead of clean dry air and nitrogen as two different types of purge gases, a system may include a source of oxygen gas as one purge gas and a source of nitrogen gas as a second type of purge gas. The nitrogen gas from the source of nitrogen gas, and the oxygen gas from the source of oxygen gas, can each be delivered to the container, optionally as a mixture.

As used herein, the term “nitrogen gas” refers to pure nitrogen gas, meaning nitrogen gas that contains at least 99.9 or 99.99 percent (molar) nitrogen, and less than 0.01 or less than 0.001 percent (molar) moisture. The term “clean dry air” refers to a gaseous composition that would be considered to be clean dry air that is sufficiently pure and moisture-free to be used in a commercial step of processing a semiconductor or microelectronic substrate; this includes gases that contain approximately 78 mole percent nitrogen (N₂), and approximately 21 mole percent oxygen (O₂), and less than 0.01 or less than 0.001 percent (molar) moisture. An example of a clean dry air product is ultra-high purity extreme clean dry air (XCDA®) available from Entegris Inc., Billerica MA. The term “oxygen gas” refers to pure oxygen gas, meaning oxygen gas that contains at least 99.9 or 99.99 percent (molar) oxygen, and less than 0.01 or less than 0.001 percent (molar) moisture.

In these or other examples, a system may handle and process (e.g., heat or cool) a purge gas to cause the purge gas to have a desired density when the purge gas is delivered to the container interior. A useful purge gas density may be a density that approximates the density of the container atmosphere that is being displaced by the purge gas; for example, a purge gas may have a density that is within 10 percent, or within 5 percent, or within 2 or 1 percent of the density of the container atmosphere. The purge gas may be a single type of purge gas, e.g., pure nitrogen (“nitrogen gas”) or clean dry air, or may be a purge gas mixture prepared from two different types of purge gas, e.g., by combining a flow of nitrogen gas from a nitrogen gas source with a flow of clean dry air from a source of clean dry air.

A wafer container includes a multi-sided container body (sometimes referred to as a “shell”) that defines a container interior that is adapted to contain and support one or more semiconductor wafers. The body includes an opening (“container opening” or “opening”) that allows access to the container interior on one side of the container body. The container also includes a door that is adapted to cover the opening and form a seal over the opening between the container interior and an exterior of the container. A substrate container can typically include at least one inlet port that is adapted to allow a gas, e.g., a “purge gas,” to be delivered to the container interior, as well as at least one (optional) outlet port that allows gas from the container interior to flow out of the interior and pass to an exterior. Optionally, a delivery device sometimes referred to as a “diffuser” may be connected to the inlet port. The diffuser may be used to distribute the purge gas throughout the container interior, for example by dispensing the purge gas along a length of the diffuser with the diffuser being located vertically along a height of the container interior.

The substrate container is adapted to contain multiple substrates. A “substrate” may be any of a variety of different generally flat structures that are known to be of a type that is commonly contained or transported in a substrate container device, to allow safe and clean handling and transport of the substrate without causing damage or contamination of the substrate. Example substrates include semiconductor wafers, precursors thereof, derivatives thereof, and in-process versions of any of these, including in-process semiconductor wafers, in-process microelectronic devices, EUV (extreme ultraviolet light) reticles, panels, or other structures known to be carried or contained in a carrier as described herein, any of which may be referred to generically as a “wafer” or a “substrate.”

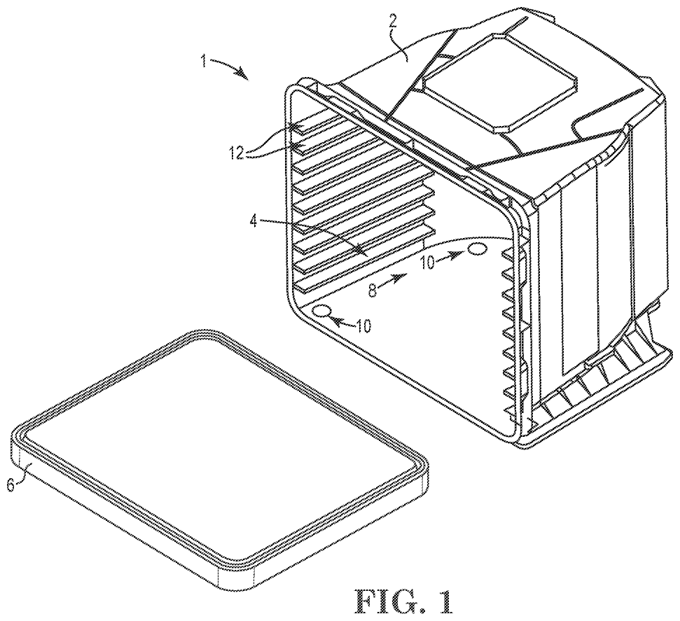

FIG. 1 shows a substrate container that can be used as a component of a substrate container system as described. Substrate container 1 includes container body (e.g. “shell”) 2, front opening 4, interior 8, ports 10 in the form of openings that pass through the bottom wall of shell 2, and slots 12 at opposite sidewalls. Slots 12 are adapted to engage and support edges of multiple substrates (not shown) as the substrates are held within interior 8. Substrate container 1 also includes door 6, which can be used to cover opening 4 to close and seal interior 8.

Substrate container 1 can be used for transporting, containing, or storing semiconductor wafers (substrates) that are being processed by a series of processing steps (i.e., wafers that are “in-process”), between steps of the series. Substrate container 1, as illustrated, is a front opening container, for example, a “front opening unified pod” or “FOUP.”

Container body 2 defines interior 8 within container 1, with opening 4 provided on one side of container body 2 to allow access to interior 8. Open side 4 allows multiple wafers to be placed inside of interior 8 of container body 2, while being supported at slots 12. Door 6 can be used to cover opening 4. When opening 4 is covered by door 6, a seal is formed by a gasket (not shown) between the door and the container. The sealed interior of container 1 is a microenvironment that is protected from contaminants that are exterior to container 1.

A substrate container as described is a component of a system, e.g., a “substrate container system,” that includes the substrate container and one or more appurtenant devices that can engage the substrate container during use, such as during steps of opening or closing the substrate container, inserting substrates into or removing substrates from the container interior, adding a gaseous atmosphere to the container interior, etc. The appurtenant devices, which may be incorporated into a system referred to as a “loadport,” may include: one or more sources of purge gas; purge gas controls that may include flow control devices to control a volume or amount of purge gas flow, a temperature control device to control a temperature of a purge gas, mixing controls to combine two flows of different purge gases into a single purge gas mixture; measurement systems to measure or monitor a condition of the container (e.g., temperature, pressure, or humidity of a container interior or atmosphere); and a control system that communicates with the substrate container system to affect or control a condition within the container or to control a condition (e.g., temperature) or flow rate of a purge gas.

Example control systems can be adapted to receive input from the substrate container system, such as temperature, pressure, or relative humidity measurements of a container atmosphere, and with that information can control a composition, temperature, or density of purge gas that is dispensed into the container interior. An example control system may perform this function using at least a computerized hardware processor with a memory device that is operatively connected to the processor. The memory can store instructions to be executed at the processor. According to various example systems of this description, a control system can include, as a computer processor, a microprocessor of any form, e.g., a process logic controller (PLC controller) embodied in an application-specific integrated circuit (ASIC), or the like.

In an example system, one or more sensors can be positioned relative to a substrate container system at locations to measure a temperature, a pressure, a relative humidity of a container atmosphere, or two or more of these. Sensors may be at a container interior, at an inlet to measure a condition of a gas flowing into the interior, at an outlet to measure a condition of a gas flowing from the container, at a source of a purge gas, or at any other effective location. A process control system can receive one or more measured values from the system and use that information to select a composition, temperature, or density of a purge gas to be delivered to the container interior. The density of the purge gas may be controlled based on the composition (chemical makeup) of the purge gas, based on the temperature of the purge gas, or a combination of these.

To deliver purge gas having a desired composition, density, or temperature, the processor is adapted to perform instructions that are stored by the memory to carry out one or more flow or temperature control functions. By one example of a useful method, a process control system measures a temperature, pressure, relative humidity, or combination thereof of a container atmosphere. The control system contains software or hardware that is programmed to use the measured conditions of the container atmosphere to determine (or approximate) the density of the container atmosphere (i.e., the “container atmosphere density” or a “container atmosphere density value”).

By one method, the control system can be programmed to use one or more measured container conditions (e.g., temperature, pressure, relative humidity of a container atmosphere) as inputs to calculations that will determine or approximate the density of the container atmosphere. As a particular example, a system may be programmed to use the Ideal Gas Law in combination with one or more other chemical relationships of humid air, with the measured temperature, pressure, and relative humidity values, to identify a container atmosphere density value.

As a different manner that is useful to determine a container atmosphere density value, the memory may include one or more correlative charts or tables that associate a density of humid air with values of conditions such as temperature, pressure, and relative humidity of the humid air. These associations may be empirically determined, may be based on a number of performed calculations (optionally iteratively), or may be determined in any other effective manner. By any useful method, the system uses measured conditions of temperature, pressure, or relative humidity, or a combination of these, and correlates the measured condition or conditions to a density of the humid air of the container atmosphere, i.e., to approximate the container atmosphere density.

Once the control system has identified a container atmosphere density value, the control system can dispense a purge gas to the container interior while controlling the density of the purge gas (“purge gas density”) to be approximately the same as the container atmosphere density value, e.g., within 10 or 5 percent of the container atmosphere density value. The purge gas density can be controlled by controlling the composition of the purge gas, by controlling the temperature of the purge gas, or by controlling both the composition and the temperature of the purge gas.

The purge gas can be supplied and delivered to the container interior according to novel methods that differ from previous methods and systems that use a single purge gas with no control of temperature of the purge gas, and without assessing or controlling density of the purge gas.

By one example method, purge gas is supplied from two different sources of purge gas, each source supplying a different type (chemical makeup) of purge gases. By such methods, the two different types of purge gases may be delivered separately to the container interior, or the two different purge gases may be combined and delivered to the container interior as a purge gas mixture.

By a different example method, a single type of purge gas or a purge gas mixture can be delivered to the container interior while controlling the temperature of the purge gas or the purge gas mixture to thereby control the density of the purge gas that is delivered to a container interior. A temperature of a purge gas or a purge gas mixture can be controlled by any method or device, such as by a cooling device or a heating device, e.g., a heat exchanger, that removes or adds heat energy to a purge gas or a purge gas mixture, or by passing a purge gas or a purge gas mixture through an orifice, with pressure, to cause the purge gas or purge gas mixture to expand and achieve a reduced temperature.

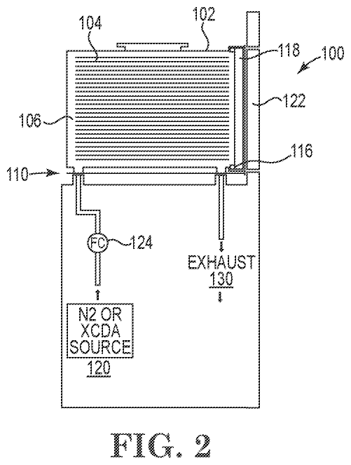

As a comparison to previous purging systems and methods, FIG. 2 shows an example of a substrate container as part of a substrate container system that does not include, but that may be adapted to include, features of a substrate container and system as described herein. System 100 includes substrate container 102 having (inner) FOUP door 118, outer (front-opening interface mechanical standard, FIMS) door 122, which may be part of a separate apparatus such as a loadport, and contains multiple substrates 104 held within interior 106. Container 102 includes inlet 110 to allow gas to flow into interior 106, and outlet 116 to allow gas to flow from interior 106 as exhaust 130 to an exterior of container 102. System 100 also includes a purge gas source 120, which may be a source of any useful purge gas such as nitrogen gas or clean dry air (e.g., “XCDA”). Flow meter 124 controls a flow of the purge gas from source 120 to inlet 110 and into interior 106. Container 102 also includes an opening (not shown) through one side of the container that allows for access to interior 106, and a door (not shown) that can be selectively placed over or removed from the opening. System 100 as illustrated does not include a second type of purge gas, and does not include a device or control system that is adapted to control the temperature or density of the purge gas that is delivered to interior 106.

In use, container 102 is used to hold substrates 104, e.g., for transporting the substrates. Substrates 104 can be initially placed within interior 106 with the door 118 of the container being removed. After substrates 104 are placed at the interior, the door 118 is placed over the opening to enclose and seal the container interior with the substrates inside. During the time when the substrates are being placed at the interior, the atmosphere within interior 106 will be that of the environment of the substrates and the container, which is typically a clean room atmosphere. A typical clean room atmosphere for processing semiconductor and microelectronic products will have a relative humidity of below 60 percent, e.g., below 50 percent, e.g., in a range from 20 to 60 percent, such as from 40 to 50 percent, at ambient temperature, e.g., approximately 22 degrees Celsius (e.g., from 20 to 25 degrees Celsius), and ambient pressure (approximately 1 atmosphere). When the door is placed over the opening, the container interior includes this clean room atmosphere, including the amount of moisture of the clean room environment.

At the time when the substrates are placed within the interior of the container, the substrates may have moisture (e.g., adsorbed moisture) at the substrate surfaces. The atmosphere of the clean room, at the container interior, may also contain moisture. When the substrates are placed into the container, the amount of moisture in the container atmosphere may change because of the wetness or dryness of the substrate surfaces. During the period of time when the substrates are contained within the enclosed container interior, moisture from the substrate surfaces will equilibrate with the moisture (humidity) within the container atmosphere. When the container is opened to remove the substrates, the container atmosphere may have a relative humidity over a large potential range, such as a relative humidity that is greater than 2 percent (at 21 degrees Celsius) and up to 100 percent, e.g., a relative humidity that may be anywhere from 5, 10, 20, or 30 percent to 50, 60, 70, 80, 90, or 100 percent at ambient temperature, e.g., 22 degrees Celsius.

For various reasons, and at different stages of handling substrates with a substrate container, the container atmosphere may be replaced with a different atmosphere, often an atmosphere of a gas that does not contain a significant amount of moisture. For example, a container atmosphere may be purged with a dry gas during or before a door of a substrate container is opened. As a different example, a container atmosphere may be purged at a time between process steps, or after a container has been closed and the container leaves a loadport. Alternately, a container atmosphere may be purged at a time after storage and movement of wafers held in a container, at a time of unloading the container while the door is removed from the container.

As part of a process of opening a substrate container to remove substrates of a type used in semiconductor and microelectronic processing, the gaseous atmosphere at the container interior may be purged to replace (displace) the container atmosphere of moist air with a new, dry gaseous atmosphere. A step of purging the container interior may be used to displace an atmosphere within the container that includes an amount of moisture in the form of humidity. The purge step may be performed with the door open (removed) or with the door closed (attached and covering the interior). The container atmosphere, which contains humidity, is replaced with a different atmosphere of a dry gas such as clean dry air or nitrogen gas (meaning pure nitrogen) to eliminate the moisture, which if allowed to remain present with the substrates can act as a contaminant or impurity at a surface of a substrate, may cause oxidation or another chemical reaction, and may reduce yield.

According to conventional methods of purging humid air from a substrate container that contains microelectronic or semiconductor substrates, the interior is purged with either nitrogen gas or clean dry air as a purge gas. Users of substrate containers in the microelectronic and semiconductor processing industries select either nitrogen gas or clean dry air as the purge gas. To the Applicant's knowledge, commercial systems and methods are not designed to use a combination of clean dry air and nitrogen gas, together, as a purge gas.

The Applicant has identified that the limited choice of using either nitrogen gas or clean dry air as a purge gas produces relatively inefficient purging of a container atmosphere of humid air. Inefficiency can result from a difference in the density of either of these types of purge gases compared to the density of a container atmosphere of humid air.

A difference in density between a purge gas and a container atmosphere can cause the flow of the purge gas through the container interior to be significantly non-uniform at different vertical locations within the container interior. A purge gas that has a higher density compared to a density of a container atmosphere will tend to flow, at least initially, along a bottom portion of the container interior, below the container atmosphere, and can tend to first displace the container atmosphere that is located at the bottom portion and more slowly displace the container atmosphere that is located at the top portion (“upper portion”) of the container. Contrariwise, a purge gas that has a lower density compared to a density of a container atmosphere will tend to flow, at least initially, along a top portion of the container interior, above the container atmosphere, and can tend to first displace the container atmosphere that is located at the top portion of the container interior and to more slowly displace the container atmosphere that is located at the lower or bottom portion of the container.

For a typical process of purging moist air from an interior of a substrate container that contains substrates used in semiconductor or microelectronic processing, the container atmosphere will be at ambient temperature and will have a relative humidity in a range from 2 to 100 percent. For many such processes, the density of the humid air will be in a range from 1.1 to 1.25 kilograms per cubic meter, e.g., from 1.15 to 1.21 kilograms per cubic meter. According to methods as described, a purge gas can have a density that approximates or matches the density of the humid air and may be within these ranges of densities. The purge gas can be of any composition, and may be prepared, processed, and handled, in any useful manner to have a density that approximates or matches the density of the humid air of the container atmosphere.

By an example technique, the density of a purge gas may be controlled by controlling the chemical makeup (composition) of the purge gas. In an example, a purge gas can contain a combination of two different types of purges gases, i.e., a purge gas mixture, with the chemical makeup of the purge gas mixture being selected to have a density that approximates the density of moist (humid) air in a container atmosphere. Clean dry air has a density that is greater than moist air, while nitrogen gas has a density that is less than moist air. A density of clean dry air may be reduced to approximate a density of humid air by increasing the concentration of nitrogen in the clean dry air—more generally, a purge gas mixture that has a density of moist air may be produced by combining a major amount of clean dry air with a lower amount of nitrogen gas. The particular density of the purge gas mixture can be controlled by controlling the relative amounts of the nitrogen gas and the clean dry air in the purge gas. According to example methods as described, the amount of nitrogen gas added to the clean dry air can be sufficient to produce a purge gas mixture that has approximately the same density as moist air of a container atmosphere that is being purged.

For a typical process of purging moist air from an interior of a substrate container that contains semiconductor or microelectronic substrates, a purge gas mixture made from (consisting of or consisting essentially of) a combination of clean dry air and nitrogen gas may contain from 50 to 97 mole percent clean dry air and from 3 to 50 percent nitrogen gas (with less than 0.01 or 0.001 mole percent water).

Considered in terms of the relative amounts of nitrogen and oxygen in a purge gas, example purge gas mixtures may contain from 78.5 or 79, up to 98.5 mole percent nitrogen and from 20.5 or 20, to 0.5 mole percent oxygen (with less than 0.01 or 0.001 mole percent water). Such a purge gas mixture may be prepared by combining clean dry air and nitrogen gas, by combining nitrogen gas and oxygen gas, or by combining any two or more different types of purge gases.

As an additional or alternate manner to control density of a purge gas, the density can be controlled by controlling the temperature of the purge gas. For example, nitrogen gas at ambient temperature has a density that is less than the density of moist air at ambient temperature. To control the density of nitrogen gas to be approximately the same as the density of the moist air (e.g., to have a density in a range from 1.1 to 1.25 kilograms per cubic meter), the temperature of the nitrogen can be controlled to be a temperature that is below the temperature of the moist air of the container atmosphere (at a common, ambient pressure). For a typical process of purging moist air from an interior of a substrate container that contains semiconductor or microelectronic substrates, nitrogen gas presented to the container atmosphere may have a temperature in a range from 11 to 15 degrees Celsius.

Clean dry air at ambient temperature has a density that is greater than the density of moist air at ambient temperature. To cause the clean dry air to have approximately the same density as moist air (e.g., to have a density in a range from 1.1 to 1.25 kilograms per cubic meter), the temperature of the clean dry air can be controlled to be a temperature that is higher than the temperature of the moist air of the container atmosphere. For a typical process of purging moist air from an interior of a substrate container that contains semiconductor or microelectronic substrates, clean dry air may be presented to the container atmosphere at a temperature in a range from 20 to 23 degrees Celsius.

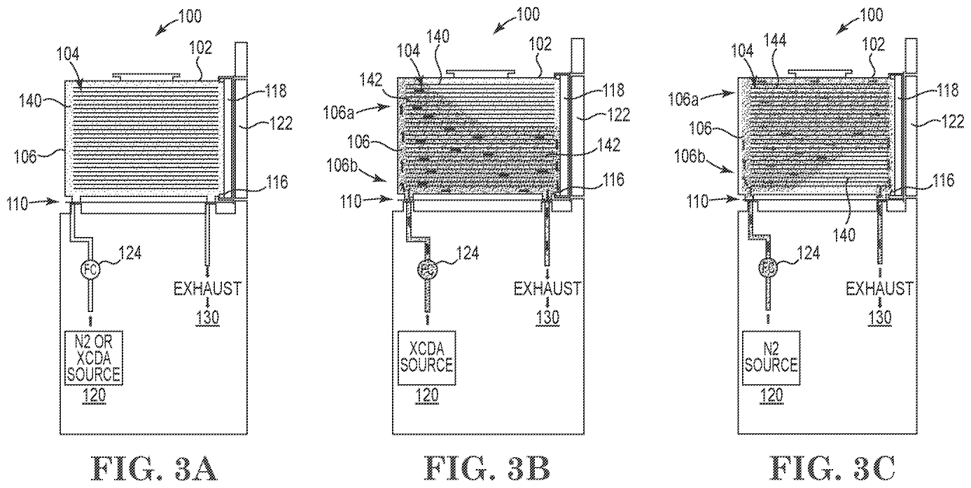

Referring to FIG. 3A, system 100 is shown to have a container atmosphere 140 of moist air (shading) of moist air that fills the interior space, including upper or top portion 106a and the lower or bottom portion 106b. In the example of FIGS. 3A, 3B, and 3C, (inner) FOUP door 118 and outer (front-opening interface mechanical standard, FIMS) door 122 are both closed. FIG. 3B shows a step of delivering clean dry air from a source of clean dry air into interior 106 through inlet 110. The clean dry air flows through interior 106 and exits interior 106 as exhaust 130. The clean dry air (darker shading) 142, which contains no moisture, has a density that is greater than a density of the moist air 140 of the container atmosphere. Having a higher density, the clean dry air 142 tends to flow through bottom portion 106b of interior 106. This results in reduced flow of clean dry air 142 through upper portion 106a, and slower displacement of moist air 140 by clean dry air 142 at upper portion 106a.

FIG. 3C shows a different example of an inefficient purge step, using nitrogen gas 144. Again referring to FIG. 3A, conventional system 100 is shown to have a container atmosphere (shaded) of moist air 140 that fills the interior space 106, including upper or top portion 106a and the lower or bottom portion 106b. FIG. 3C shows a step of delivering nitrogen gas 144 from a source of nitrogen gas 120 into interior 106 through inlet 110. The nitrogen gas 144 has a density that is less than a density of the moist air of container atmosphere 140. The nitrogen gas 144 tends to flow more through upper portion 106a of interior 106. This results in reduced flow of nitrogen gas 144 through bottom portion 106b, and slower displacement of moist air container atmosphere 140 by nitrogen gas 144 at the bottom portion 106b.

Methods and systems of the present description can perform a step of purging a moist air atmosphere of a substrate container in a manner that has improved uniformity of flow between a top portion and a bottom portion of an interior of a container. A purge step that involves improved uniformity of flow of purge gas through different portions (top and bottom portions) of a substrate container can be more efficient, e.g., may be completed in a shorter amount of time, compared to a purge step that has non-uniform flow of purge gas at the different top and bottom portions of the container interior. In example methods and systems, the density of a purge gas that is used to displace the moist air container atmosphere is controlled to approximate the density of the container atmosphere that is being displaced.

In example systems, a substrate container system can include sensors and a process control system that are adapted to determine (e.g., assess or approximated) a value of the density of the container atmosphere that is being displaced from the container interior. Using the process control system, the substrate container system can determine a density value of the container atmosphere and in response to that density value can control the density of purge gas that enters the container interior to displace the container atmosphere.

Conditions of the system, including temperature, pressure, and relative humidity of a container atmosphere, can be measured by sensors adapted to measure these conditions. Any one of more of these sensors can be included as part of the system at a location that will be effective to measure the condition. For example, a sensor may be located at a container interior, or at or near an outlet of a container.

Using one or more of the measured conditions, a density value of the humid air container atmosphere can be determined or approximated by comparing those conditions to information stored in memory of the process control system that correlates previously assessed and tabulated conditions of pressure, temperature, and relative humidity of humid air to density values of humid air. Alternately, the measured conditions may be used to calculate a value of the density of the humid air of the container atmosphere using known mathematical equations that can identify a density value of humid air based on a measured relative humidity, pressure, temperature, or combination of these.

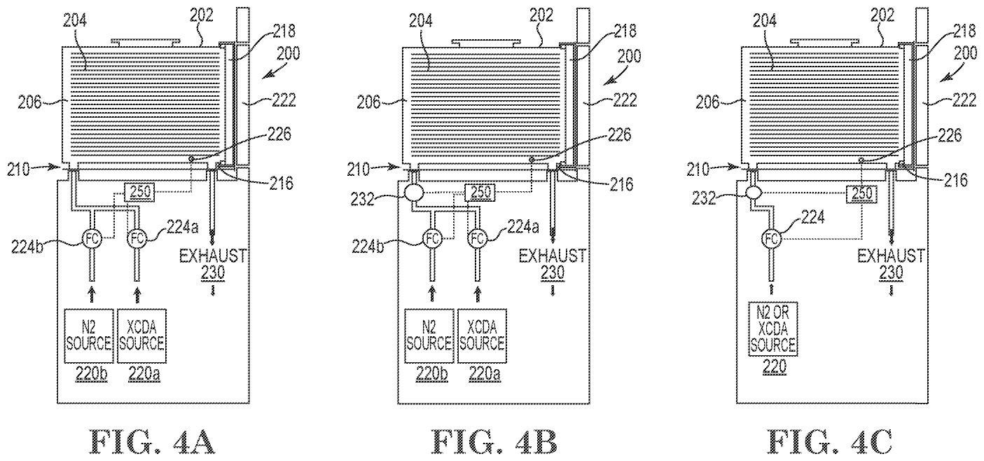

An example system of the present description is shown at FIG. 4A. Illustrated is system 200, which includes substrate container 202, which contains multiple substrates 204 held within interior 206. Container 202 includes inlet 210 to allow purge gas to flow into interior 206, and outlet 216 to allow gas to flow from interior 206 as exhaust 230 to an exterior of container 202. Container 202 also includes an opening (not shown) through one side of the container that allows for access to interior 206, and an inner door 218 that can be selectively placed over or removed from the opening. Outer door 222, e.g., of a loadport, can also be selectively opened and closed to allow access to inner door 218 and container 200.

System 200 also includes two separate purge gas sources, 220a and 220b, which may be sources of any two different purge gases, such as a source of nitrogen gas and a source of clean dry air. Flow meters 224a and 224b independently control the flows of the two different purge gases from sources 220a and 220b to inlet 210 and into interior 206. As shown, the two different purge gases that flow from the two different purge gas sources 220a and 220b are combined to form a single combined purge gas (or “purge gas mixture”) that flows into inlet 210.

Substrate container system 200 also includes a control system that includes microprocessor 250 connected to sensors and flow control devices of system 200. Microprocessor 250 is connected to both flow control devices 224a and 224b, and to one or more sensors 226 that are adapted to measure one or more of pressure, temperature, or relative humidity of moist air of a container atmosphere at interior 206. The process control system can measure conditions of the container atmosphere, determine a density value of the container atmosphere, and based on the density value can deliver a purge gas mixture to interior 206 that has a density that approximates the density value of the moist air container atmosphere. The system may control the density of the purge gas by combining nitrogen gas and clean dry air in relative amounts that will produce a purge gas mixture that has a density that approximates the density value of the container atmosphere.

As a different example, system 200 of FIG. 4B likewise includes two separate purge gas sources, 220a and 220b, and additionally includes temperature control device 232 that may be used to control the temperature of a purge gas mixture produced by combining an amount of nitrogen gas from source 220b with clean dry air from source 220a. The temperature of the purge gas mixture may be controlled to further control the density of the purge gas mixture delivered to interior 206.

Referring to FIG. 4C, system 200 includes only a single source of purge gas 220, which may be either a source of nitrogen gas or a source of clean dry air, or a different gas. Flow meter 224 controls the flow of the purge gas from source 220 to inlet 210 and into interior 206. System 200 also includes temperature control device 232 that is useful to control the temperature and consequently a density of a purge gas delivered from source 220 to interior 206.

A substrate container system 200 as illustrated includes a control system that includes microprocessor 250 connected to sensors and flow control devices of system 200. Referring to FIG. 4A, microprocessor 250 is connected to both flow control devices 224a and 224b, and to one or more sensors 226 that are adapted to measure one or more of pressure, temperature, or relative humidity of moist air of a container atmosphere that will be contained at interior 206. The process control system of example substrate container systems 200 of FIGS. 4B and 4C are comparable, except that: the control system of FIG. 4B additionally communicates with temperature control device 232; the control system of FIG. 4C communicates with temperature control device 232 but only communicates with a single flow meter 224.

The process control system of each example can measure conditions of the container atmosphere, determine (by any useful method or approximation) a density value of the container atmosphere, and based on the density value can deliver a purge gas or purge gas mixture to interior 206 that has a density that approximates the density value of the container atmosphere; the example systems control the density of the purge gas by controlling the composition of a purge gas mixture (FIG. 4A), by controlling a temperature of a single type of purge gas (FIG. 4C), or by controlling both a temperature and a composition of a purge gas mixture (FIG. 4B).

In use, container 202 of each example holds substrates 204, e.g., for transporting the substrates. While substrates 204 are being placed at interior 206, the atmosphere within interior 206 will be that of the environment of the substrates and container, which is typically a clean room atmosphere. The substrates 204 may have moisture (e.g., adsorbed moisture) at the substrate surfaces and that moisture will become moisture within the container atmosphere. At a time when the container is opened, the container atmosphere may have any relative humidity that is greater than 2 percent (at ambient temperature such as 22 degrees Celsius), e.g., a relative humidity that may be anywhere from 5 to 100 percent, typically from 40 to 50 percent (at ambient temperature, such as 22 degrees Celsius). To remove the moist air of the container atmosphere, the container interior is purged with a dry purge gas.

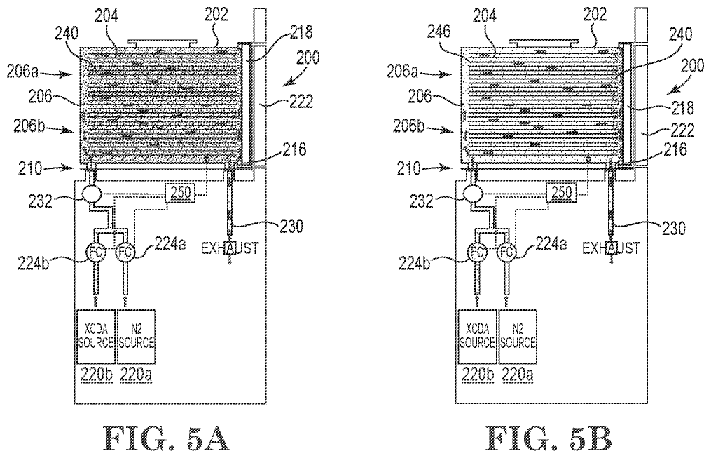

Referring to FIG. 5A, system 200 of FIG. 4B is shown to have container atmosphere 240 (shaded) that fills interior space 206, including upper or top portion 206a and the lower or bottom portion 206b. FIG. 5B shows a step of delivering purge gas mixture 246 (lighter shading) prepared by combining two different sources of purge gas, e.g., a source of clean dry air 220b and a source of nitrogen 220a, into interior 206 through inlet 210.

At FIG. 5B, the purge gas density can be controlled by controlling the composition of the purge gas mixture 246 (i.e., relative amounts of nitrogen gas and clean dry air), or by controlling a temperature of purge gas mixture 246, or by controlling both composition and temperature of purge gas mixture 246. Alternately, an example system may control purge gas density of a single type of purge gas (not a mixture) by controlling only purge gas temperature (see FIG. 4C), or by controlling only purge gas composition (see FIG. 4A).

In each example (FIGS. 4A, 4B, and 4C), container atmosphere 240 has a density, which can be determined or estimated by any useful measurement technique, calculation, or comparison of conditions of atmosphere 240 to empirical data that correlates pressure, temperature, or relative humidity of moist air to density of moist air. A purge gas (e.g., a purge gas mixture) 246 can be controlled to have a composition, temperature, or both, that will result in a purge gas density that is approximately equal to the density of the container atmosphere 240. This results in relatively uniform flow of purge gas 246 through upper portion 206a and lower portion 206b, as shown at FIG. 5B.

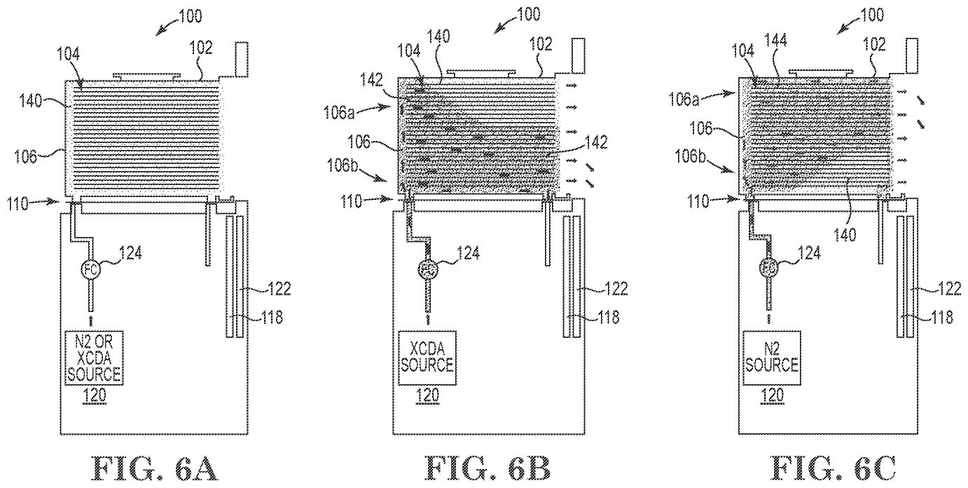

Example systems and methods can also be useful to perform a purge step of a container while doors 118 and 122 are in opened positions with the front opening of the container being uncovered to allow removal of wafers from interior 106, as shown at FIGS. 6A, 6B, and 6C.

Referring to FIG. 6A, conventional system 100 is shown to have a container atmosphere 140 (shading) of moist air that fills the interior space, including upper or top portion 106a and the lower or bottom portion 106b. At FIG. 6A FOUP door 118 and outer door 122 are lowered relative the front of container to uncover the front opening of the container and allow access to interior 106 and wafers held therein.

FIG. 6B shows a step of delivering clean dry air from a source of clean dry air into interior 106 through inlet 110. The clean dry air flows through interior 106 and exits interior 106 through the un-covered front opening (see arrows). The clean dry air (darker shading) 142, which contains no moisture, has a density that is greater than a density of the moist air of container atmosphere 140. Having a higher density, the clean dry air tends to flow through bottom portion 106b of interior 106. This results in reduced flow of clean dry air 142 through upper portion 106a and slower displacement of container atmosphere 140 by clean dry air 142 at upper portion 106a. According to the present description,

FIG. 6C shows a different example of an inefficient purge step, using nitrogen gas 144. Again referring to FIG. 6A, conventional system 100 is shown to have a container atmosphere 140 (shaded) of moist air that fills the interior space, including upper or top portion 106a and the lower or bottom portion 106b. FIG. 6C shows a step of delivering nitrogen gas 144 from a source of nitrogen gas 120 into interior 106 through inlet 110. The nitrogen gas 144 flows through interior 106 and exits interior 106 through the un-covered front opening (see arrows). The nitrogen gas 144 has a density that is less than a density of the moist air 140 of the container atmosphere. The nitrogen gas 144 tends to flow more through upper portion 106a of interior 106. This results in reduced flow of nitrogen gas 144 through bottom portion 106b and slower displacement of container atmosphere 140 by nitrogen gas 144 at the bottom portion 106b.

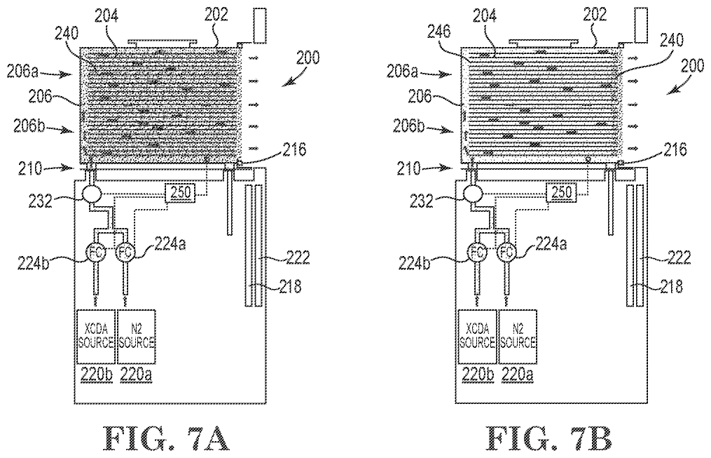

Referring to FIG. 7A, system 200 is shown to have container atmosphere 240 (shaded) of moist air that fills interior space 206, including upper or top portion 206a and the lower or bottom portion 206b. FIG. 7B shows a step of delivering purge gas mixture 246 (lighter shading) prepared by combining two different sources of purge gas, e.g., a source of clean dry air 220b and a source of nitrogen 220a, into interior 206 through inlet 210.

At FIG. 7B, the purge gas density can be controlled by controlling the composition of the purge gas mixture 246 (i.e., relative amounts of nitrogen gas and clean dry air), or by controlling a temperature of purge gas mixture 246, or by controlling both composition and temperature of purge gas mixture 246. Alternately, an example system may control purge gas density of a single type of purge gas (not a mixture) by controlling only purge gas temperature (see FIG. 4C), or by controlling only purge gas composition (see FIG. 4A).

Aspects:

Aspect 1. A method of purging a substrate container with purge gas, the substrate container comprising:
a container body comprising an opening,
a door adapted to cover the opening,
an interior defined by the container body,
substrates supported within the interior,
a container atmosphere within the interior, and
one or more purge gas inlets at the interior;
   the method comprising
dispensing purge gas through the one or more inlets to the interior, the purge gas comprising:
   clean dry air received from a source of clean dry air, and
   nitrogen gas received from a source of nitrogen gas.

Aspect 2. The method of aspect 1, wherein the clean dry air comprises approximately 78 mole percent nitrogen (N₂), and approximately 21 mole percent oxygen (O₂).

Aspect 3. The method of aspect 1 or 2, wherein the nitrogen gas has a purity of at least 99.99 mole percent nitrogen.

Aspect 4. The method of any of aspect 1 through 3, comprising:
combining the clean dry air with the nitrogen gas to produce a purge gas mixture that has a gas mixture density,
dispensing the purge gas mixture through an inlet, and
controlling the purge gas mixture density to approximate a density of the container atmosphere.

Aspect 5. The method of aspect 4, wherein the purge gas mixture comprises:
from 50 to 97 mole percent clean dry air, and
from 3 to 50 mole percent nitrogen gas.

Aspect 6. The method of aspect 4, wherein the purge gas mixture comprises:
from approximately 78.5 mole percent to 98.5 mole percent nitrogen, and
from approximately 20.5 mole percent to 0.5 mole percent oxygen.

Aspect 7. The method of any of aspects 4 through 6, wherein the purge gas mixture density is within 5 percent of the container atmosphere density.

Aspect 8. The method of any of aspects 4 through 7, wherein the purge gas mixture flows with better uniformity between an upper portion of the interior and a lower portion of the interior, compared to a comparable flow of only clean dry air, and compared to a comparable flow of nitrogen gas.

Aspect 9. The method of any of aspects 4 through 8, comprising measuring a humidity, a pressure, and a temperature of the container atmosphere and forming the purge gas mixture from amounts of clean dry air and nitrogen based on the humidity, pressure, or temperature of the container atmosphere.

Aspect 10. The method of any of aspects 1 through 10, wherein the purge gas mixture has a density in a range from 1.15 to 1.21 kilograms per cubic meter.

Aspect 11. The method of any of aspects 1 through 10, wherein the door is removed and the opening is uncovered.

Aspect 12. The method of any of aspects 1 through 10, wherein the door covers the opening.

Aspect 13. A method of purging a substrate container with purge gas, the substrate container comprising:
a container body comprising an opening,
a door adapted to cover the opening,
an interior defined by the container body,
substrates supported within the interior,
a container atmosphere within the interior,
a purge gas inlet at the interior, and
a source of purge gas;
   the method comprising:
measuring relative humidity of the container atmosphere,
controlling a density of the purge gas based on the relative humidity of the container atmosphere, and
   dispensing the purge gas through the inlet and into the interior.

Aspect 14. The method of aspect 13, wherein
the source of purge gas comprises:
   a source of clean dry air, and
   a source of nitrogen gas,
the purge gas comprises a purge gas mixture that contains:
   a flow of clean dry air received from the source of clean dry air, and
   a flow of nitrogen gas received from the source of nitrogen gas, and
the method comprises selecting the rate of the flow of clean dry air, and the rate of the flow of nitrogen gas, to control the density of the purge gas mixture.

Aspect 15. The method of aspect 13 or 14, comprising controlling a temperature of the purge gas mixture to control the density of the of the purge gas.

Aspect 16. The method of aspect 13, wherein the purge gas consists of clean dry air and the method comprises controlling a temperature of the clean dry air to control the density of the clean dry air.

Aspect 17. The method of aspect 13, wherein the purge gas consists of nitrogen gas and the method comprises controlling a temperature of the nitrogen gas to control the density of the nitrogen gas.

Aspect 18. The method of aspect 17, comprising controlling a temperature of the purge gas by flowing the purge gas through an orifice to increase a volume of the purge gas and change a temperature of the purge gas.

Aspect 19. The method of any of aspects 13 through 18, comprising controlling the purge gas density to be within 10 percent of the container atmosphere density.

Aspect 20. The method of any of aspects 13 through 19, wherein as the purge gas is dispensed into the interior, the purge gas has a density in a range from 1.15 to 1.21 kilograms per cubic meter.

Aspect 21. The method of any of claims 13 through 20, comprising:
measuring a humidity, a pressure, and a temperature of the container atmosphere, and
controlling a density of the purge gas based on the relative humidity, the pressure, and the temperature of the container atmosphere.

Aspect. 22. The method of any of aspects 13 through 21, wherein the door is removed and the opening is uncovered.

Aspect 23. The method of any of aspects 13 through 21, wherein the door is removed and the opening is uncovered.

Aspect 24. A substrate container system comprising:
a container body comprising an opening,
a door adapted to be placed over and removed from the opening,
an interior defined by the container body,
substrates supported within the interior,
a container atmosphere within the interior,
a purge gas inlet at the interior,
a source of purge gas comprising:
   a source of clean dry air, and
   a source of nitrogen gas, and
a purge gas flow control system that combines a flow of the clean dry air and a flow of the nitrogen gas to produce a purge gas mixture.

Aspect 25. The substrate container system of aspect 24, wherein the control system comprises:
a first flow meter to control a flow of the clean dry air to the purge gas inlet,
a second flow meter to control a flow of the nitrogen gas to the purge gas inlet.

Aspect 26. The substrate container system of aspects 24 or 25 comprising a temperature control device to control a temperature of the purge gas.

Aspect 27. The substrate container system of aspect 25, wherein the temperature control device is a mechanical orifice.

Aspect 28. The substrate container system of any of aspects 24 through 27 comprising a relative humidity sensor, wherein the purge gas flow control system selects a flow rate of the clean dry air, or a flow rate of the nitrogen gas, or flow rates of the clean dry air and the nitrogen gas based on a measured relative humidity of the system.

Aspect 29. A substrate container system comprising:
a container body comprising an opening,
a door adapted to be placed over and removed from the opening,
an interior defined by the container body,
a purge gas inlet connected to the interior,
a relative humidity sensor,
a source of purge gas, and
a control system to control a density of purge gas dispensed through the purge gas inlet to the interior.

Aspect 30. The substrate container of aspect 29, wherein the control system comprises a mechanical orifice in a flow of a purge gas to reduce a temperature of the purge gas as the purge gas flows through the mechanical orifice.

Aspect 31. The substrate container of aspect 27 or 28, wherein
the source of purge gas comprises:
   a source of clean dry air, and
   a source of nitrogen gas, and
the control system comprises:
a flow meter to control a flow of the clean dry air to the purge gas inlet,
   a flow meter to control a flow of the nitrogen to the purge gas inlet.

Aspect 32. The substrate container of aspect 30 or 31, the source of purge gas consisting of a source of clean dry air, the control system comprising a temperature control device to control a temperature of the clean dry air.

Aspect 33. The substrate container of aspect 30 or 31, the source of purge gas consisting of a source of nitrogen gas, the control system comprising a temperature control device to control a temperature of the nitrogen gas.

Aspect 34. A method comprising dispensing a purge gas mixture through an inlet of a substrate container, wherein the purge gas mixture comprises a combination of clean dry air and nitrogen gas.

Aspect 35. The method of aspect 34, wherein the purge gas mixture comprises:
from 50 to 97 mole percent clean dry air, and
from 3 to 50 mole percent nitrogen gas.

Aspect 36. The method of aspect 34, wherein the purge gas mixture has a density in a range from 1.1 to 1.25 kilograms per cubic meter.

Aspect 37. The method of any of aspects 34 through 36, wherein the door is removed and the opening is uncovered.

Aspect 38. The method of any of aspects 34 through 36, wherein the door is removed and the opening is uncovered.

What is claimed is:

1. A substrate container system comprising:
a container body comprising an opening,
a door adapted to be placed over and removed from the opening,
an interior defined by the container body,
substrates supported within the interior,
a container atmosphere within the interior,
a purge gas inlet at the interior,
a source of purge gas comprising:
a source of clean dry air, and
a source of nitrogen gas, and
a purge gas flow control system that combines a flow of the clean dry air and a flow of the nitrogen gas to produce a purge gas mixture.

2. The substrate container system of claim 1, wherein the control system comprises:
a first flow meter to control a flow of the clean dry air to the purge gas inlet,
a second flow meter to control a flow of the nitrogen gas to the purge gas inlet.

3. The substrate container system of claim 2 comprising a temperature control device to control a temperature of the purge gas.

4. The substrate container system of claim 2, wherein the temperature control device is a mechanical orifice.

5. The substrate container system of any of claim 4 comprising a relative humidity sensor, wherein the purge gas flow control system selects a flow rate of the clean dry air, or a flow rate of the nitrogen gas, or flow rates of the clean dry air and the nitrogen gas based on a measured relative humidity of the system.

6. The substrate container system of claim 10, further comprising a pressure sensor and a temperature sensor.

7. The substrate container system of claim of 11, wherein the humidity sensor measures a humidity, the pressure sensor measures a pressure, and the temperature sensor measures a temperature of the container atmosphere and the control system forms a purge gas mixture from amounts of the clean dry air and the nitrogen based on the humidity, pressure, or temperature of the container atmosphere.

8. A substrate container system comprising:
a container body comprising an opening,
a door adapted to be placed over and removed from the opening,
an interior defined by the container body,
a purge gas inlet connected to the interior,
a relative humidity sensor,
a source of purge gas, and
a control system to control a density of purge gas dispensed through the purge gas inlet to the interior.

9. The substrate container system of claim 8, wherein the control system comprises a mechanical orifice in a flow of a purge gas to reduce a temperature of the purge gas as the purge gas flows through the mechanical orifice.

10. The substrate container system of claim 9, wherein
the source of purge gas comprises:
a source of clean dry air, and
a source of nitrogen gas, and
the control system comprises:
a flow meter to control a flow of the clean dry air to the purge gas inlet,
a flow meter to control a flow of the nitrogen to the purge gas inlet.

11. The substrate container system of claim 10, the source of purge gas consisting of a source of clean dry air, the control system comprising a temperature control device to control a temperature of the clean dry air.

12. The substrate container system of claim 10, the source of purge gas consisting of a source of nitrogen gas, the control system comprising a temperature control device to control a temperature of the nitrogen gas.

13. The substrate container system of claim 12, further comprising a pressure sensor and a temperature sensor.

14. The substrate container system of claim of 13, wherein the humidity sensor measures a humidity, the pressure sensor measures a pressure, and the temperature sensor measures a temperature of the container atmosphere and the control system forms a purge gas mixture from amounts of the clean dry air and the nitrogen based on the humidity, pressure, or temperature of the container atmosphere.

15. A method of purging a substrate container with purge gas, the substrate container comprising:
a container body comprising an opening,
a door adapted to cover the opening,
an interior defined by the container body,
substrates supported within the interior,
a container atmosphere within the interior, and
one or more purge gas inlets at the interior;
the method comprising
dispensing purge gas through the one or more inlets to the interior, the purge gas comprising:
clean dry air received from a source of clean dry air, and
nitrogen gas received from a source of nitrogen gas.

16. The method of any of claim 15, comprising:
combining the clean dry air with the nitrogen gas to produce a purge gas mixture that has a gas mixture density,
dispensing the purge gas mixture through an inlet, and
controlling the purge gas mixture density to approximate a density of the container atmosphere.

17. The method of any of claim 16, wherein the purge gas mixture density is within 5 percent of the container atmosphere density.

18. The method of any of claim 17, wherein the purge gas mixture flows with better uniformity between an upper portion of the interior and a lower portion of the interior, compared to a comparable flow of only clean dry air, and compared to a comparable flow of nitrogen gas.

19. The method of any of claim 18, comprising measuring a humidity, a pressure, and a temperature of the container atmosphere and forming the purge gas mixture from amounts of clean dry air and nitrogen based on the humidity, pressure, or temperature of the container atmosphere.

20. The method of any of claim 19, wherein the purge gas mixture has a density in a range from 1.15 to 1.21 kilograms per cubic meter.
